(19) United States
(12) Patent Application Publication
(10) Pub. No.: US 2025/0359129 A1
(43) Pub. Date: Nov. 20, 2025

(54) TUNING WORK FUNCTIONS OF COMPLEMENTARY TRANSISTORS

(71) Applicant: Taiwan Semiconductor Manufacturing Co., Ltd., Hsinchu (TW)

(72) Inventors: Hsueh-Ju Chen, Taipei City (TW); Tsung-Da Lin, Hsinchu (TW); Chi On Chui, Hsinchu (TW)

(21) Appl. No.: 19/281,860

(22) Filed: Jul. 28, 2025

Related U.S. Application Data
(63) Continuation of application No. 18/358,383, filed on Jul. 25, 2023.
(60) Provisional application No. 63/500,002, filed on May 4, 2023.

(51) Int. Cl. H10D 30/62; H10D 30/67; H10D 62/13; H10D 64/01; H10D 64/68; H10D 84/83

(52) U.S. Cl. CPC H10D 30/62; H10D 30/6735; H10D 30/6757; H10D 62/154; H10D 62/158; H10D 64/017; H10D 64/691; H10D 84/834

(57) ABSTRACT

A method includes forming a source/drain region based on a first portion of a semiconductor region, forming an interfacial layer base on a second portion of the semiconductor region, forming a dipole film on the interfacial layer, depositing a high-k dielectric layer on the dipole film, and depositing a work-function layer on the high-k dielectric layer.

### PRIORITY CLAIM AND CROSS-REFERENCE

This application is a continuation of U.S. patent application Ser. No. 18/358,383, filed on Jul. 25, 2023, which application claims the benefit of the following provisionally filed U.S. Patent application: Application No. 63/500,002, filed on May 4, 2023, and entitled “Complementary Metal-Oxide-Semiconductor and Forming Method Thereof,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3, 4A, 4B, 5-9, 10A-10G, and 11 illustrate the views of intermediate stages in the formation of complementary transistors including a dipole film in accordance with some embodiments.

FIGS. 12A-12D illustrate the views of intermediate stages in the formation of complementary transistors including a dipole film in accordance with some embodiments.

FIGS. 13A-13E illustrate the views of intermediate stages in the formation of complementary transistors including a dipole film in accordance with some embodiments.

FIGS. 14A-14G illustrate the views of intermediate stages in the formation of complementary transistors including a dipole film in accordance with some embodiments.

FIGS. 15A-15H illustrate the views of intermediate stages in the formation of complementary transistors including a dipole film in accordance with some embodiments.

FIGS. 16A-16J illustrate the views of intermediate stages in the formation of complementary transistors including a dipole film in accordance with some embodiments.

FIG. 17 illustrates a view in the formation of a Gate-All-Around (GAA) transistor in accordance with some embodiments.

FIG. 18 illustrates a distribution profile of a dipole dopant in a gate stack in accordance with some embodiments.

FIG. 19 illustrates a process flow for forming complementary transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary transistors including dipole films and the method of forming the same are provided. In accordance with some embodiments, Complementary transistors including a p-type transistor and an n-type transistor are formed to share a common gate electrode, with a same work-function layer being formed in both of the p-type transistor and the n-type transistor. One of the transistors has a dipole film incorporated between the interfacial layer and the overlying high-k dielectric layer, so that its effective work function falls into the desirable work function range. Although Fin Field-Effect Transistors (FinFETs) are used as an example, the concept of the present disclosure may also be applied to other types of transistors such as planar transistors, Gate-All-Around (GAA) transistors, and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

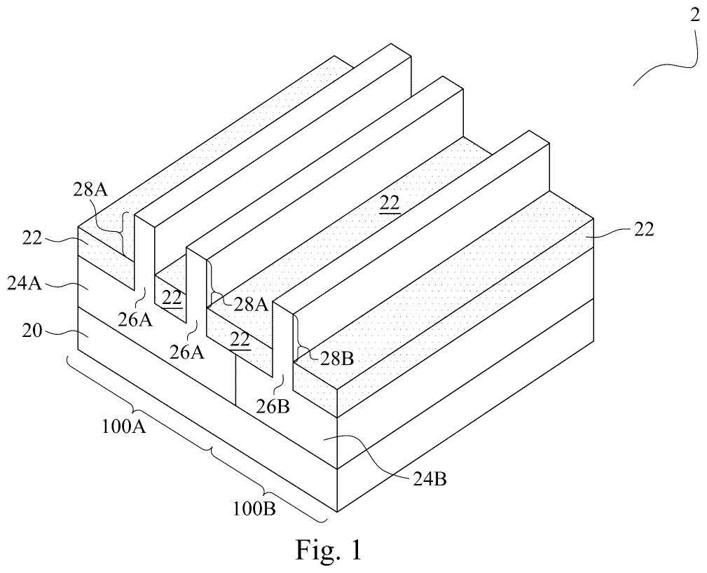

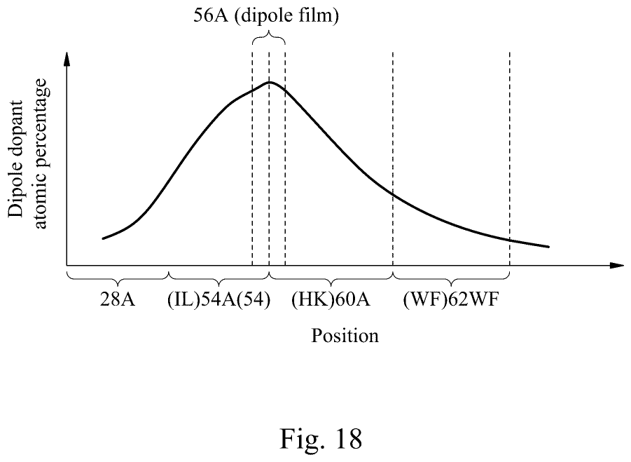

FIGS. 1-3, 4A, 4B, 5-9, 10A-10G, and 11 illustrate the cross-sectional views of intermediate stages in the formation of complementary transistors sharing a common gate in accordance with some embodiments. The corresponding processes are also reflected schematically in the process flow shown in FIG. 18.

FIG. 1 illustrates a perspective view of an initial structure. The initial structure includes wafer 2 including substrate 20, which may be a semiconductor substrate. Substrate 20 may be a silicon substrate, a silicon germanium substrate, or a substrate formed of other semiconductor materials. Device region 100A and 100B are illustrated, in which complementary FinFETs are to be formed. In accordance with some embodiments, device region 100A is for forming an nFET (which is an n-type FinFET), and device region 100B is for forming a pFET (which is a p-type FinFET). In accordance with alternative embodiments, device region 100A is for forming a pFET, and device region 100B is for forming an nFET. In subsequent discussion, device regions 100A and 100B are referred to as the nFET region and pFET region, respectively, to simplify the discussion.

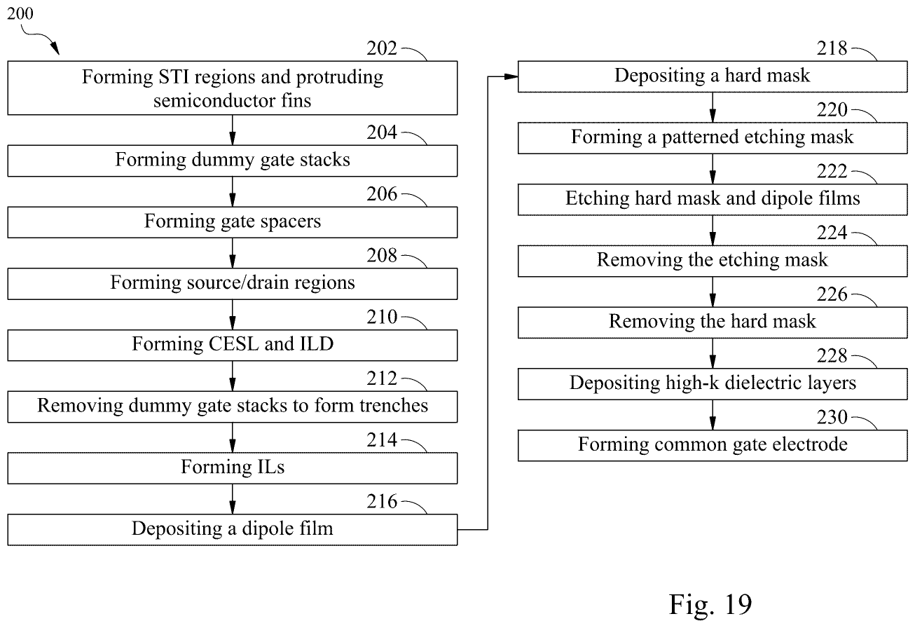

Isolation regions 22 such as Shallow Trench Isolation (STI) regions may be formed to extend into substrate 20. The portions of substrate 20 between neighboring STI regions 22 are referred to as semiconductor strips 26, which include semiconductor strips 26A in device region 100A and semiconductor strips 26B in device region 100B. Well regions 24A and 24B are formed in device regions 100A and 100B, respectively, and extend into semiconductor strips 26A and 26B, respectively. The top portions of semiconductor strips 26 protrude higher than the top surfaces of STI regions 22, and are referred to as protruding semiconductor fins 28, which include 28A and 28B in device regions 100A and 100B, respectively. The formation of STI regions 22 and protruding semiconductor fins 28 may include recessing bulk semiconductor substrate 20 to form recesses, depositing dielectric materials into the recesses, planarizing the top surface of the semiconductor substrate 20 with the top surface of STI regions 22, and then recessing STI regions 22. The respective process is illustrated as process 202 in the process flow 200 as shown in FIG. 19.

In accordance with some embodiments, the fins for forming the FinFETs may be formed/patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

Referring to FIG. 2, dummy gate stacks 30 are formed on the top surfaces and the sidewalls of protruding fins 28A and 28B. The respective process is illustrated as process 204 in the process flow 200 as shown in FIG. 19. Dummy gate stacks 30 may include dummy gate dielectrics 32 and dummy gate electrodes 34 over dummy gate dielectrics 32. Dummy gate electrodes 34 may be formed using, for example, amorphous silicon or polysilicon, and other materials may also be used. Each of dummy gate stacks 30 may also include one (or a plurality of) hard mask layer 36 over dummy gate electrode 34. Hard mask layers 36 may be formed of silicon nitride, silicon carbo-nitride, or the like. Dummy gate stacks 30 also have lengthwise directions perpendicular to the lengthwise directions of protruding fins 28A and 28B.

Next, gate spacers 38 are formed on the sidewalls of dummy gate stacks 30. The respective process is illustrated as process 206 in the process flow 200 as shown in FIG. 19. In accordance with some embodiments, gate spacers 38 are formed of dielectric materials such as silicon carbon-oxynitride (SiCN), silicon nitride, silicon oxy-carbon-oxynitride (SiOCN), or the like, and may have a single-layer structure or a multi-layer structure including a plurality of dielectric layers.

FIG. 2 also illustrates the processes for forming source/drain regions 42A in device region 100A and source/drain regions 42B in device region 100B. The respective process is illustrated as process 208 in the process flow 200 as shown in FIG. 19. In accordance with some embodiments in which device regions 100A and 100B are n-type region and p-type region, respectively, source/drain regions 42A and source/drain regions 42B are of n-type and p-type, respectively. The formation of source/drain regions 42A may include recessing the portions of protruding fins 28A that are not covered by gate spacers 38 and dummy gate stacks 30 to form recesses, and epitaxially growing a corresponding semiconductor material (an n-type semiconductor material, for example) from the recesses. The formation of source/drain regions 42B may include recessing the portions of protruding fins 28B that are not covered by gate spacers 38 and dummy gate stacks 30 to form recesses, and epitaxially growing a corresponding semiconductor material (a p-type semiconductor material, for example) from the recesses.

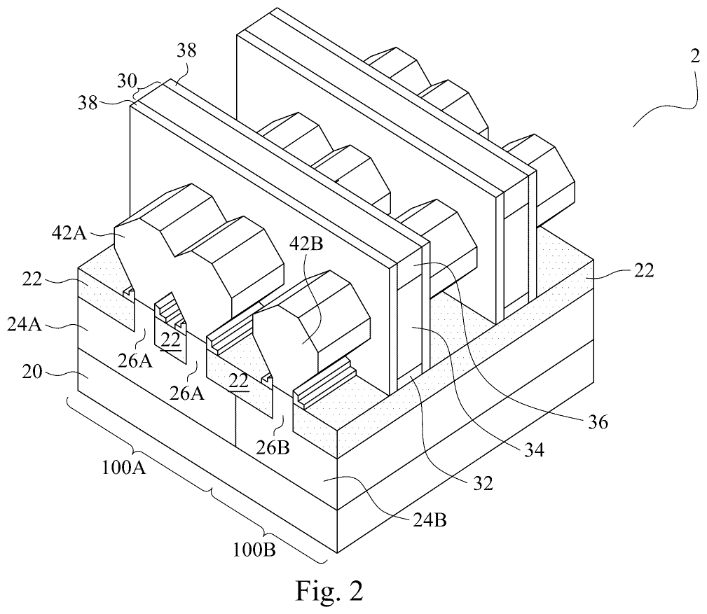

Next, referring to FIG. 3, Contact Etch Stop Layer (CESL) 46 and Inter-Layer Dielectric (ILD) 48 are formed. The respective process is illustrated as process 210 in the process flow 200 as shown in FIG. 19. In accordance with some embodiments, CESL 46 may be formed of or comprise silicon oxide, silicon nitride, silicon carbide, silicon carbonitride, or the like, or combinations thereof. ILD 48 may also be formed of an oxygen-containing dielectric material, which may be a silicon-oxide based dielectric material such as silicon oxide, Phospho-Silicate Glass (PSG), Boro-Silicate Glass (BSG), Boron-Doped Phospho-Silicate Glass (BPSG), or the like. A planarization process such as a Chemical Mechanical Polish (CMP) process or a mechanical grinding process may be performed to level the top surfaces of ILD 48, CESL 46, dummy gate stacks 30, and gate spacers 38 with each other.

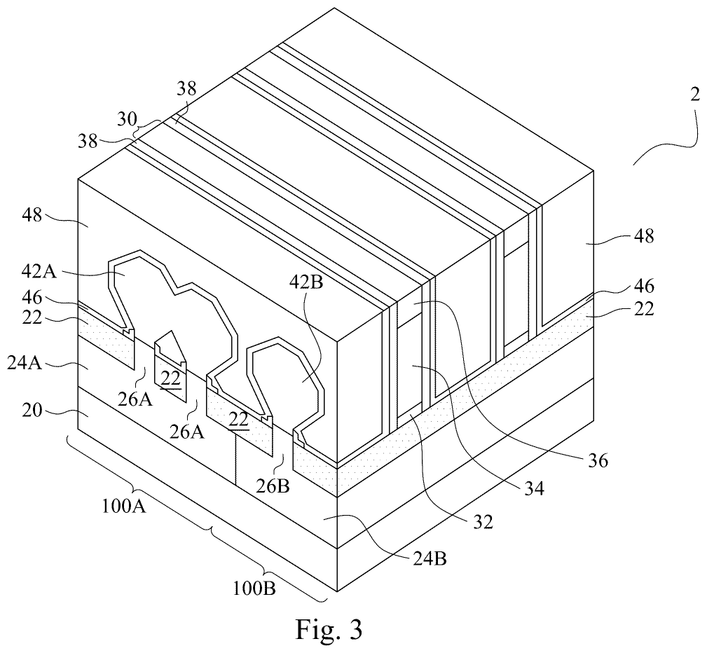

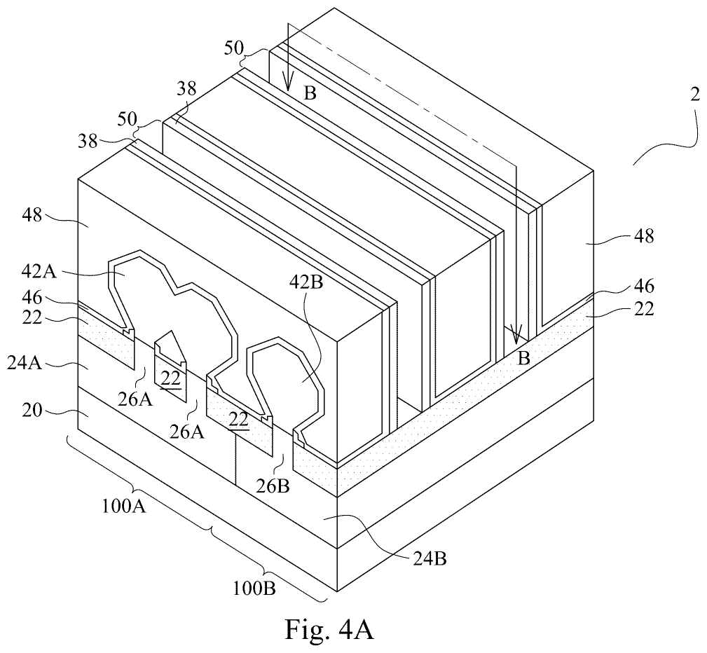

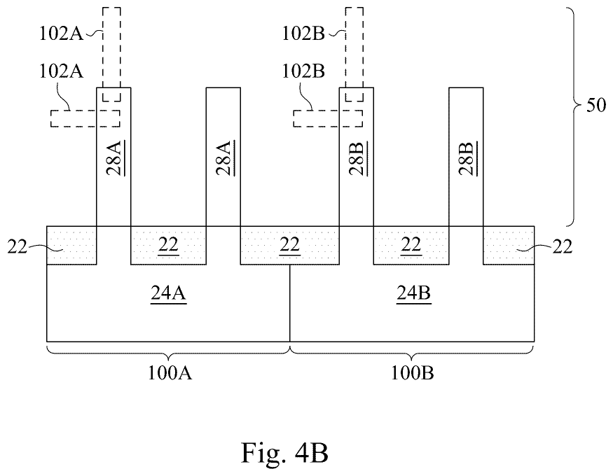

Dummy gate stacks 30 are then removed, hence form trenches 50 between gate spacers 38, as shown in FIG. 4A. The respective process is illustrated as process 212 in the process flow 200 as shown in FIG. 19. The removal of dummy gate stacks 30 may include a plurality of etching processes. The etching processes are performed until the underlying protruding semiconductor fins 28A and 28B (refer to FIG. 4B) are exposed.

FIG. 4B illustrates a cross-section B-B in FIG. 4A, wherein the cross-section passes through one of the trenches 50. Protruding fins 28A and 28B are underlying, and are exposed to, trench 50. Protruding fins 28A form a first fin group, and protruding fins 28B form a second fin group. The first fin group is separated from the second fin group by one of STI regions 22.

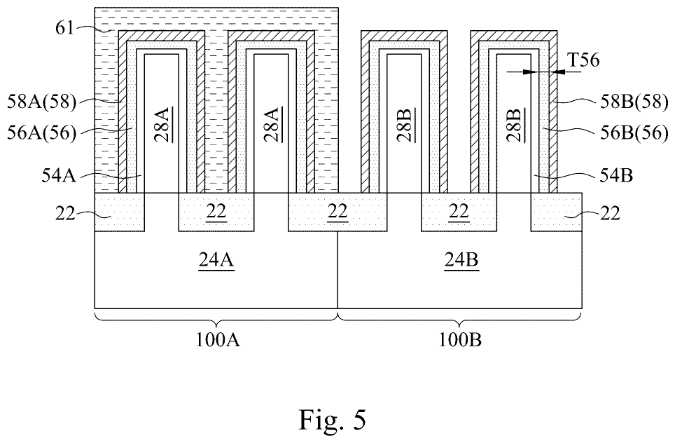

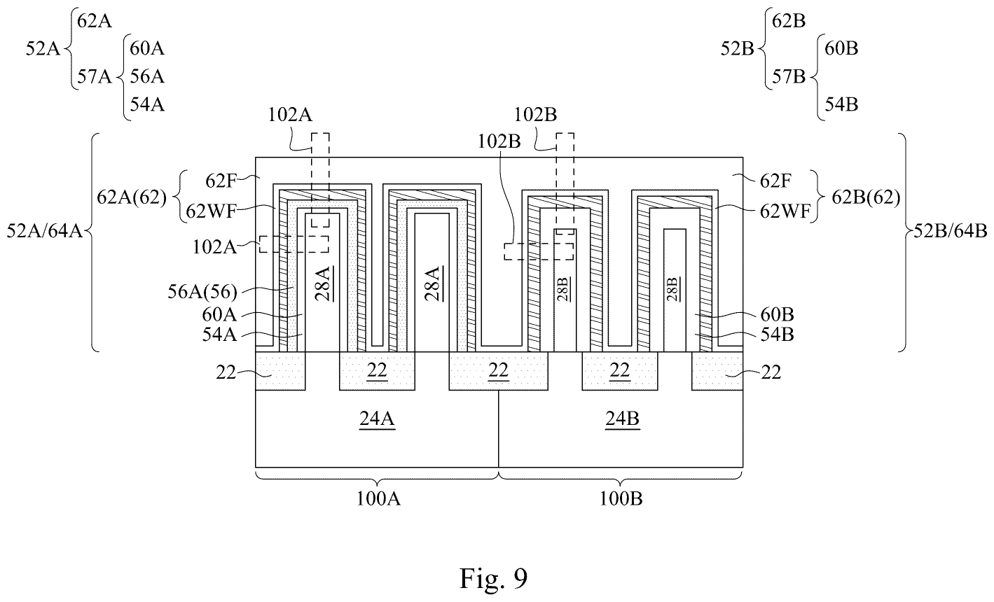

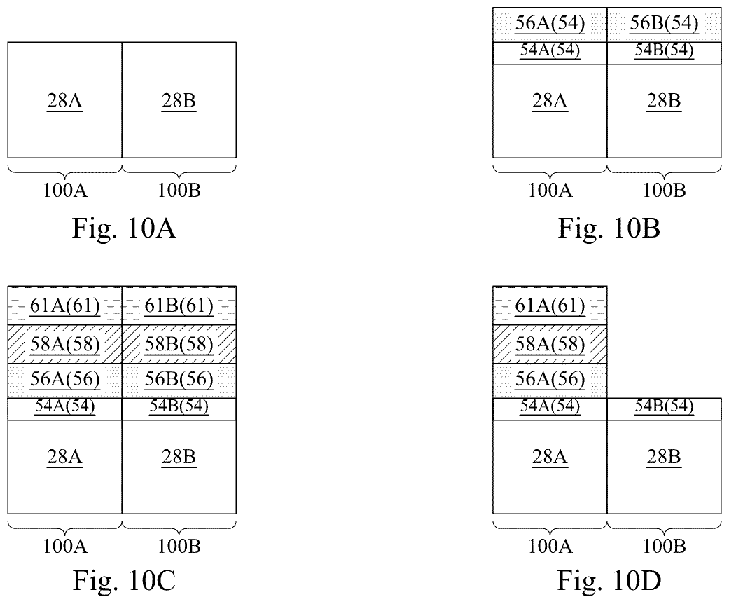

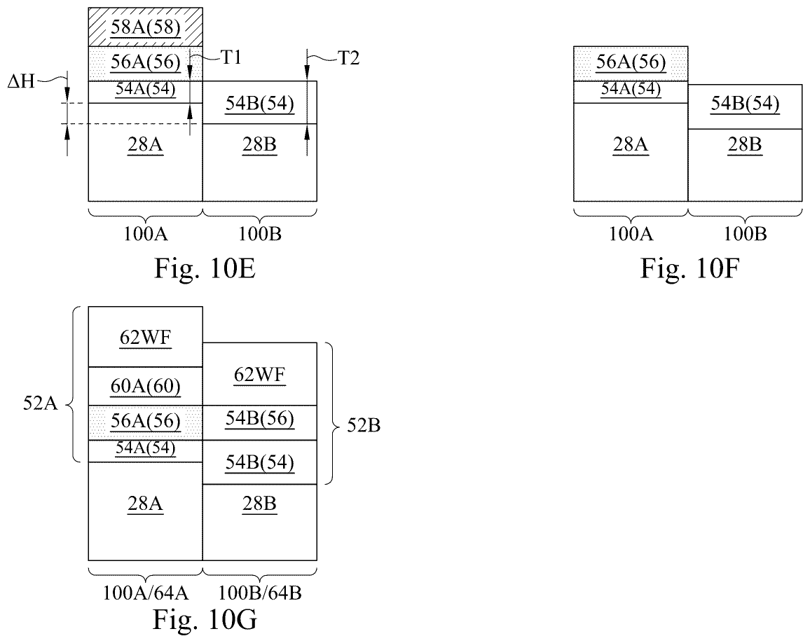

FIGS. 5 through 9 illustrate a brief process for forming replacement gate stacks 52A and 52B (FIG. 9) in accordance with some embodiments. The formation of replacement gate stacks 52A and 52B may be achieved through one of a plurality of candidate processes as shown in FIGS. 10A-10G, 12A-12D, 13A-13E, 14A-14G, 15A-15H, and 16A-16J, as will be discussed in detail in subsequent paragraphs. It is appreciated that the processes shown in FIGS. 5 through 9 are simplified, and more details may be found referring to the processes shown in FIGS. 10A-10G, 12A-12D, 13A-13E, 14A-14G, 15A-15H, and 16A-16J.

FIG. 5 illustrates the processes following the process as shown in FIG. 4B. In accordance with some embodiments, Interfacial Layers (ILs) 54A and 54B are formed on protruding fins 28A and 28B, respectively. The respective process is illustrated as process 214 in the process flow 200 as shown in FIG. 19. Each of ILS 54A and 54B may include an oxide layer such as a silicon oxide layer, which may be formed through the thermal oxidation of the surface parts of protruding fins 28A and 28B, a chemical oxidation process, or a deposition process. Depending on which of the processes 10A-10G, 12A-12D, 13A-13E, 14A-14G, 15A-15H, and 16A-16J is adopted, the thickness of ILS 54A may be equal to, greater than, or smaller than the thickness of ILS 54B, and/or the material of ILs 54A may be the same as or different from the material of ILS 54B.

Dipole film 56 is deposited on ILs 54A and 54B. Dipole film 56 includes portions 56A on ILs 54A, and portions 56B on ILs 54B. The respective process is illustrated as process 216 in the process flow 200 as shown in FIG. 19. In accordance with some embodiments in which device region 100A is an nFET region and device region 100B is a pFET region, dipole film 56 is an n-type dipole film comprising an n-type dipole dopant therein. The n-type dipole dopant may include La, Sc, Er, Sr, Y, and/or the like, or combinations thereof. For example, dipole film 56 may include a compound of the n-type dopant, which compound may be an oxide, a nitride, and/or an oxynitride of the n-type dipole dopant. The compound may be a metal compound.

In accordance with alternative embodiments in which device region 100A is a pFET region, and device region 100B is an nFET region, dipole film 56 is a p-type dipole film comprising a p-type dipole dopant therein. The p-type dipole dopant may include Al, Zn, Nb, and/or the like, or combinations thereof. For example, dipole film 56 may include a compound of the p-type dopant, which compound may be an oxide, a nitride, and/or an oxynitride of the p-type dipole dopant. The compound may be a metal compound.

In accordance with some embodiments, dipole film 56 is deposited as a very thin film, which may have the thickness T56 smaller than about 10 Å. Thickness T56 may also be in the range between about 1 Å and about 10 Å, or may be smaller than about 1 Å. The formation process may include a conformal deposition process such as Atomic Layer deposition (ALD), plasma enhanced ALD, or the like. The process gases may include a precursor, a reactant, and a dilute gas. For example, when the dipole dopant comprises La, the respective precursor may include La(thd)₃, La(fAMD)₃, La(Cp)₃, La(iPrCP)₃, or the like, or combinations thereof. The reactant may include H₂O, O₃, O₂, NH₃, H₂, or the like, or combinations thereof. The dilute gas may include N₂, Ar, H₂, or the like, or combinations thereof. The deposition temperature may be in the range between about 100° C. and about 500° C. The pressure of the deposition chamber may be in the range between about 0.1 Torr and about 100 Torr.

Further referring to FIG. 5, hard mask 58 is deposited on dipole film 56. The respective process is illustrated as process 218 in the process flow 200 as shown in FIG. 19. In accordance with some embodiments, hard mask 58 may be a dielectric hard mask formed of or comprising silicon nitride, silicon oxynitride, silicon oxy-carbide, or the like. Hard mask 58 may also be a metal hard mask comprising titanium nitride, tantalum nitride, tungsten nitride, titanium carbide, tantalum carbide, tungsten carbide, or the like.

Etching mask 61 is formed over hard mask 58, and is patterned. The respective process is illustrated as process 220 in the process flow 200 as shown in FIG. 19. Etching mask 61 may be a single-layer hard mask, a tri-layer hard mask layer, or the like. For example, the single-layer hard mask may be a photoresist layer. The tri-layer hard mask may include a Bottom Anti-Reflective Coating (BARC, which may be formed of a cross-linked photoresist), a middle layer (not shown) over the BARC, and a top layer (not shown) over the middle layer. The etching mask 61 is patterned, and is removed from device region 100B and left unremoved in device region 100A.

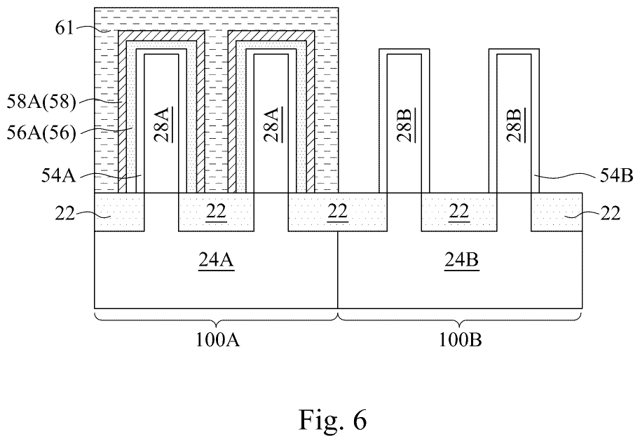

The patterned etching mask 61 is used to etch hard mask 58, and to remove hard mask portion 58B. The resulting structure is shown in FIG. 6, Next, dipole film 56 is etched, and the portions 56B if dipole film 56 are removed from device region 100B. The respective process is illustrated as process 222 in the process flow 200 as shown in FIG. 19. ILs 54B are thus exposed. The etching processes may be performed either using the remaining etching mask 61 as the etching mask, or the remaining portions 58A of hard mask 58 as the etching mask.

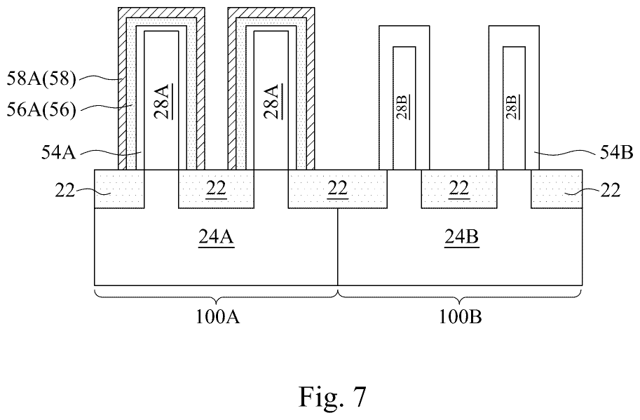

Etching mask 61, if any remaining, is then removed. The respective process is illustrated as process 224 in the process flow 200 as shown in FIG. 19. The resulting structure is shown in FIG. 7. The removal may be performing through an ashing process, which may be performed using an oxygen-containing gas as the process gas. Alternatively, etching mask 61 is removed through etching.

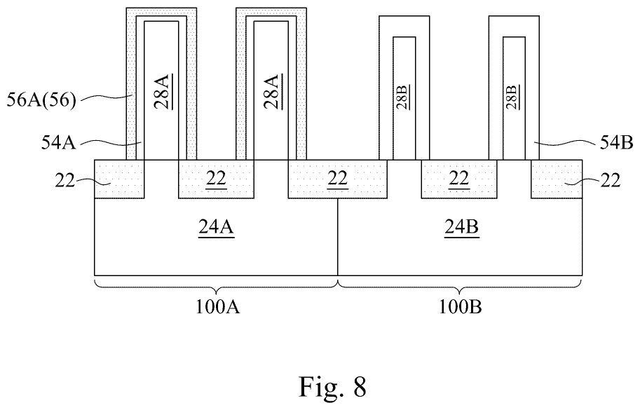

Hard mask 58 is also removed. The respective process is illustrated as process 226 in the process flow 200 as shown in FIG. 19. The resulting structure is shown in FIG. 8. In device region 100A, the portion 56A of the dipole film 56 remain, and is in contact with ILs 54A. In device region 100B, ILs 54B are exposed. Depending on which of the processes 10A-10G, 12A-12D, 13A-13E, 14A-14G, 15A-15H, and 16A-16J is adopted, protruding fins 28B may be (or may not be) oxidized and thinned. Accordingly, protruding fins 28B may be shorter and thinner than protruding fins 28A, as shown in FIG. 8, or may have the same height and same thickness as protruding fins 28A.

In a subsequent process, as shown in FIG. 9, high-k dielectric layers 60A and 60B are deposited. The respective process is illustrated as process 228 in the process flow 200 as shown in FIG. 19. Depending on which of the processes 10A-10G, 12A-12D, 13A-13E, 14A-14G, 15A-15H, and 16A-16J is adopted, high-k dielectric layers 60A and 60B may be formed of a same material or different materials, and/or having a same thickness or different thicknesses. Furthermore, depending on which of the processes 10A-10G, 12A-12D, 13A-13E, 14A-14G, 15A-15H, and 16A-16J is adopted, high-k dielectric layers 60A may be formed of a homogeneous high-k dielectric material, or may include two high-dielectric layers formed of different materials. The materials of high-k dielectric layers 60A and 60B may be selected from hafnium oxide, zirconium oxide, lanthanum oxide, and/or the like, combinations thereof, and/or composite layers thereof.

In accordance with some embodiments, during an entire period of time starting from the time dipole film 56 starts to be deposited (FIG. 5) and ending at the time gate stacks 52A and 52B have been formed, no annealing for driving the dipole dopant in dipole film 56A into ILs 54 and the overlying high-k dielectric layers is performed. It is appreciated that some deposition processes may be performed at elevated temperature, while the drive-in process (if performed) would not result in the deposition of materials.

Gate electrode 62 is formed on high-k dielectric layers 60A and 60B. The respective process is illustrated as process 230 in the process flow 200 as shown in FIG. 19. The portions of gate electrode 62 in device regions 100A and 100B are formed in the common processes, and hence have the same structures and same materials. Gate electrode 62 includes portion 62A in device region 100A, and portion 62B in device region 100B. Gate electrode portion 62A is continuously connected to gate electrode portion 62B, with no distinguishable interface in between. Since gate electrode portions 62A and 62B are formed in common processes and there is no boundary in between, there is no boundary effect generated, which boundary effect occurs when the gate electrodes of the complementary transistors are formed in different processes and are joined together.

Gate electrode 62 may include a work-function layer 62WF, and may or may not include filling metal 62F over work-function layer 62WF. The work-function layer 62WF may be an n-type work-function layer having a low work function, and may include TiAlN, TiAl, TiAlC, TaAlC, TaAlN, or the like, or multi-layers thereof. Alternatively, the work-function layer 62WF may be a p-type work-function layer having a high work function, and may include TiN, TiSiN, TaN, WCN, MOCN or the like, or multi-layers thereof.

ILs 54A, dipole film 56A, and high-k dielectric layers 60A collectively form gate dielectric 57A. Gate dielectric 57A and gate electrode portion 62A collectively form gate stack 52A for the transistor 64A in device region 100A. ILs 54B and high-k dielectric layers 60B collectively form gate dielectric 57B. Gate electrode portion 62B and gate dielectric 57B collectively form gate stack 52B for the transistor 64B in device region 100B. In accordance with some embodiments, no dipole film removal process is performed, and hence the dipole film (and/or the materials in the dipole film) remain in the final transistors.

In accordance with some embodiments in which transistor 64A is an nFET and transistor 64B is a pFET, dipole film 56A is an n-type dipole film, work-function layer 62WF is a p-type work function layer which has a high work function, for example, higher than about 4.6 eV, and may be in the range between about 4.6 eV and about 5.2 eV. Accordingly, dipole film 56A comprises an n-type dipole dopant, which brings down the effective work function of the n-type work-function layer 62WF into the nFET to the n-type work function range, for example, between about 4.0 eV and about 4.5 eV.

In accordance with alternative embodiments in which transistor 64A is a pFET and transistor 64B is an nFET, dipole film 56A is a p-type dipole film, work-function layer 62WF is an n-type work function layer which has a low work function, for example, between about 4.0 eV and about 4.5 eV. Accordingly, dipole film 56A comprises a p-type dipole dopant, which brings up the effective work function of the n-type work-function layer 62WF in the pFET into the p-type work function range, for example, higher than about 4.6 eV, and may be in the range between about 4.6 eV and about 5.2 eV.

FIGS. 10A-10G, 12A-12D, 13A-13E, 14A-14G, 15A-15H, and 16A-16J illustrate the formation of gate stacks in accordance with various embodiments, and provide more process details of the processes shown in FIGS. 5 through 9. In the discussion of these embodiments, some details may have already been discussed when FIGS. 5 through 9 are discussed, and hence the process details of these embodiments may be combined the discussion of the embodiments shown in FIGS. 5 through 9. Also, the description provided for any of the embodiments shown in FIGS. 10A-10G, 12A-12D, 13A-13E, 14A-14G, 15A-15H, and 16A-16J may be applied to other embodiments whenever applicable.

FIG. 10A through 10F illustrate some example detailed views of the processes shown in FIGS. 5 through 9 in accordance with some embodiments. Device regions 100A and 100B are also illustrated side-by-side. Also, the structures in device region 100A as shown in FIGS. 10A through 10F (and the figures in subsequently discussed other embodiments) may be obtained from the corresponding regions such as regions 102A in FIG. 4B, and the structure in device region 100B as shown in FIGS. 10A through 10F (and the figures in subsequently discussed other embodiments) may be obtained from corresponding regions such as regions 102B in FIG. 4B.

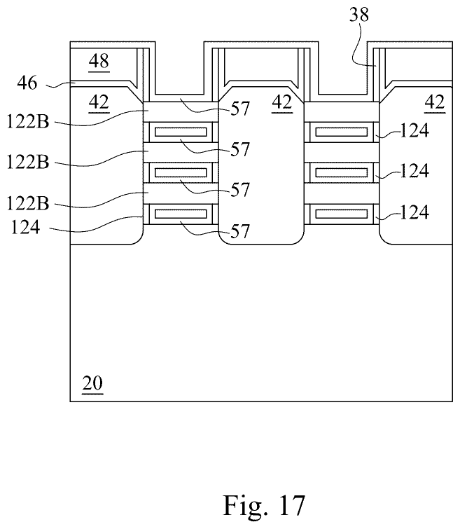

Referring to FIG. 10A, the semiconductor regions 28A and 28B as obtained from device regions 100A and 100B are illustrated. Device regions 100A and 100B may be the protruding semiconductor fins as shown in FIG. 4B, the nanostructures 122B as shown in FIG. 17 for forming GAA transistors, or the like. It is appreciated that although semiconductor regions 28A and 28B are placed side-by-side and appear to be in contact with each other, they may be obtained from the regions that are close to, but not in contact with each other, as illustrated in FIGS. 4B and 17 in accordance with some example embodiments.

Referring to FIG. 10B, ILs 54A and 54B are formed, and may be formed in a common process, for example, through the oxidation of the underlying semiconductor regions 28A and 28B, or through a deposition process. Next, dipole film 56, which includes portions 56A and 56B, is deposited over ILs 54A and 54B. In the example embodiment in which device region 100A is an nFET region, dipole film 56 is an n-type dipole film. Conversely, in the example embodiment in which device region 100A is a pFET region, dipole film 56 is a p-type dipole film.

Referring to FIG. 10C, hard mask 58, which includes portions 58A and 58B, is deposited over dipole film 56. Etching mask 61 is then formed, and may include portions 61A and 61B in device regions 100A and 100B, respectively. Next, etching mask 61 is patterned and is removed from device region 100B. Hard mask portion 58B and dipole film portion 56B are also removed through etching, with etching mask portion 61A (or hard mask portion 58A) being used to define patterns. The resulting structure is shown in FIG. 10D. The remaining etching mask 61 is then removed, and the resulting structure is shown in FIG. 10E.

Due to the lithography process and the possible removal of etching mask 61, the thickness of IL 54B may be increased due to the further oxidation of semiconductor region 28B, while semiconductor region 28A has less oxidation than semiconductor region 28B due to the protection of hard mask 58. Accordingly, thickness T2 of IL 54B is greater than thickness T1 of IL 54A. In accordance with some embodiments, ratio T2/T1 is greater than about 1.5, and may be greater than about 2.0. Furthermore, due to the oxidation of semiconductor region 28B, the top surface of semiconductor region 28B may be lowered, for example, to a level lower than the top surface of semiconductor region 28A. The height difference ΔH may be greater than about 2 Å, and maybe in the range between about 2 Å and about 10 Å.

Hard mask 58 is then removed. The resulting structure is shown in FIG. 10F. Dipole film 56 remains in device region 100A, and has been removed from device region 100B. In a subsequent process, as shown in FIG. 10G, high-k dielectric layers 60 (including portions 60A and 60B) and gate electrode 62 (with work-function layer 62WF shown) are formed. FIG. 10G illustrates work-function layer 62WF, while there may be, or may not be, filling metal regions 62F (not shown in FIG. 10G, referring to FIG. 9) formed over work-function layer 62WF. Filling metal regions 62F may be formed of tungsten, cobalt, aluminum, or the like, or alloys thereof, and may include a homogeneous material extending into both of device regions 100A and 100B. A planarization process is then performed to remove excess portions of the formed layers, and to form gate stacks 52A and 52B, which are also shown in FIG. 9.

FIG. 11 illustrates the subsequent processes. In FIG. 11, gate stack 52B is revealed, while gate stack 52A is on the side that is not visible. Gate stacks 52A and 52B are first recessed through etching to form recesses. A dielectric material is then filled into the recesses, followed by an additional planarization process to remove the excess portions of the dielectric material higher than the top surfaces of ILD 48, so that self-aligned hard masks 66 are formed. In subsequent process, additional features (not shown) such as source/drain silicide regions, source/drain contact plugs, gate plugs, and the like are formed. Complementary transistors 64A and 64B are thus formed, which share a continuous gate stack 52. Also, since the gate spacers 38 have been exposed to the dipole film 56, there may be dipole dopant found in the gate spacers 38.

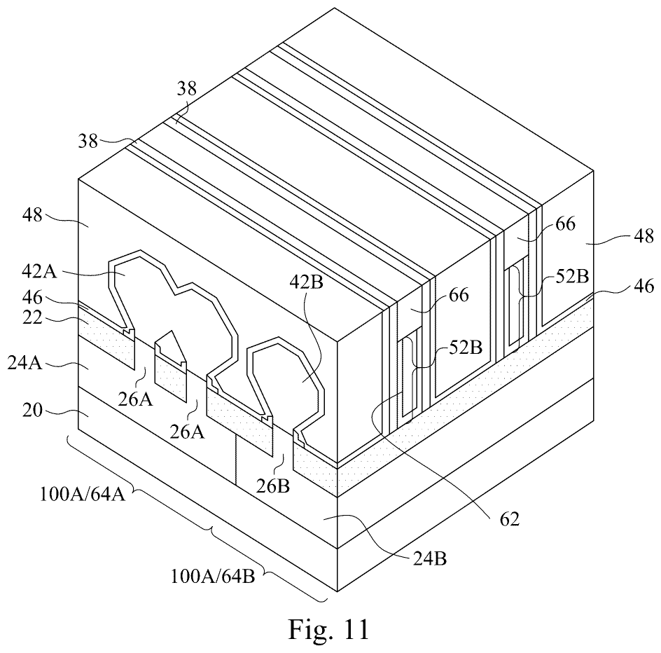

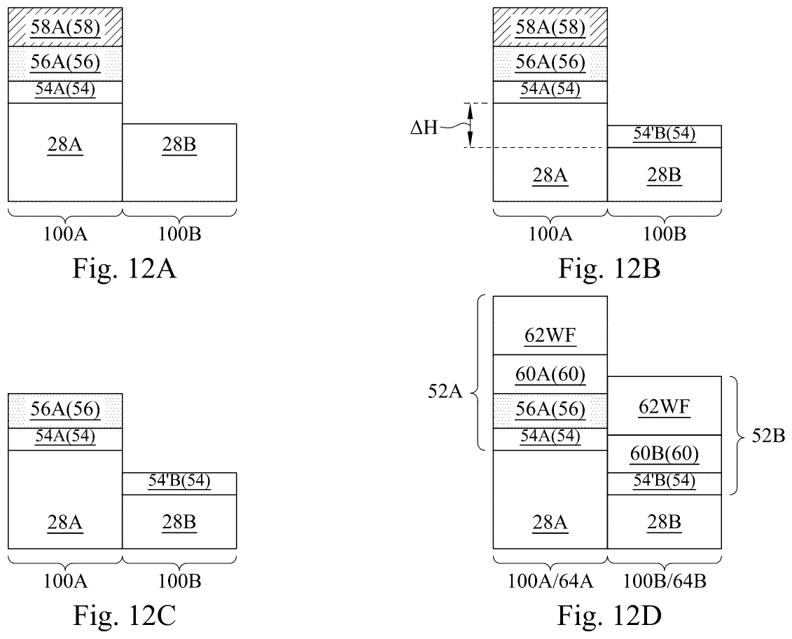

FIGS. 12A through 12D illustrate the formation of gate stacks in accordance with alternative embodiments. These embodiments are similar to the embodiments as shown in FIGS. 10A through 10G, except that in the embodiments as shown in FIGS. 10A through 10G, the IL 54B is not replaced, while in the embodiments as shown in FIGS. 12A through 12D, the IL 54B is replaced with IL 54′B through re-formation.

The initial processes are the same as shown in FIGS. 10A through 10E, and are not repeated herein. Next, the IL 54B as shown in FIG. 10E is removed through etching, and the resulting structure is shown in FIG. 12A. In FIG. 12B, IL 54′B is re-formed as a replacement IL. The material of IL 54′B may be the same as or different from the material of IL 54A. Furthermore, the top surface of semiconductor region 28B may be lower than the top surface of semiconductor region 28A by height difference ΔH. Hard mask 58A is then removed, and the resulting structure is shown in FIG. 12C. In a subsequent process, high-k dielectric layers 60A and 60B and work function layer 62WF are formed.

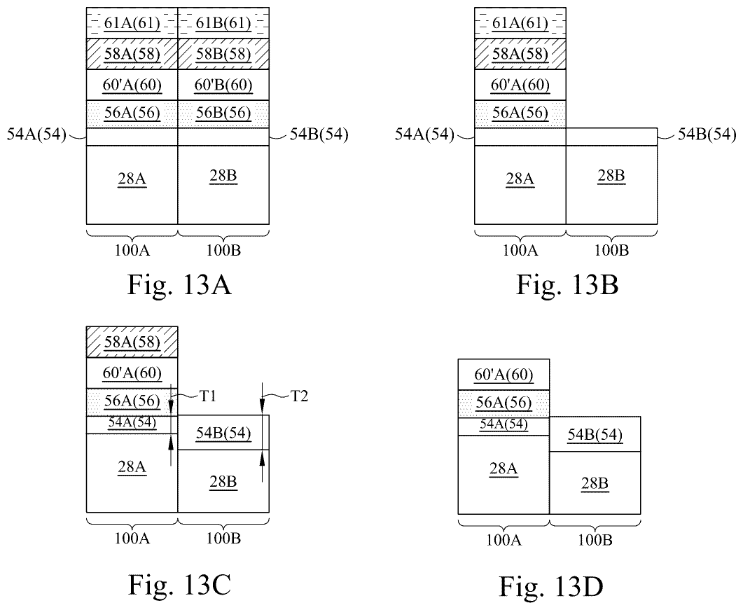

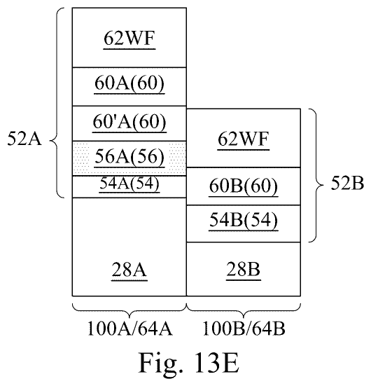

FIGS. 13A through 13D illustrate the formation of gate stacks in accordance with alternative embodiments. These embodiments are similar to the embodiments as shown in FIGS. 10A through 10G, except that an additional high-k dielectric layer is formed before the removal of the dipole film from device region 100B, and the additional high-k dielectric layer is left in the transistor 64A.

The initial processes are the same as shown in FIGS. 10A and 10B, and are not repeated herein. Next, as shown in FIG. 13A, an additional high-k dielectric layer 60′ is deposited, which includes portions 60′A and 60′B. High-k dielectric layer 60′ may comprise a high-k dielectric material different from, or same as, the dielectric material of the subsequently deposited high-k dielectric layer 60 (FIG. 13E). Hard mask 58 is then deposited, followed by the formation of etching mask 61.

Referring to FIG. 13B, the etching mask 61 is patterned to remove the portion 61B, followed by the etching processes to remove hard mask portion 58B, portion 60′A of high-k dielectric layer 60, and dipole film portion 56B. IL 54B is thus revealed. Next, etching mask 61 is removed, resulting in the structure shown in FIG. 13C. The thickness of IL 54B may be increased by the removal processes of etching mask 61A. High-k dielectric layer 60′ may have the function of protecting the underlying layers. The remaining hard mask 58 is then removed, with the resulting structure shown in FIG. 13D. FIG. 13E illustrates the formation of high-k dielectric layer 60 and the work-function layer 62WF.

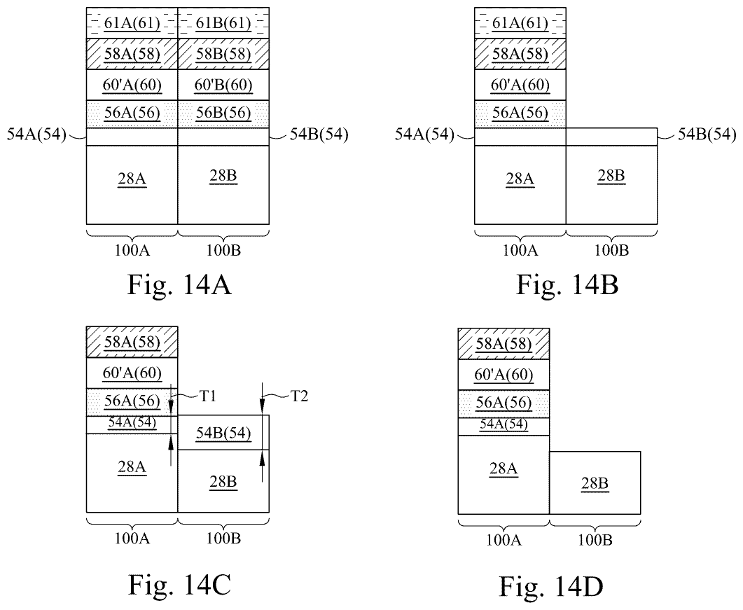

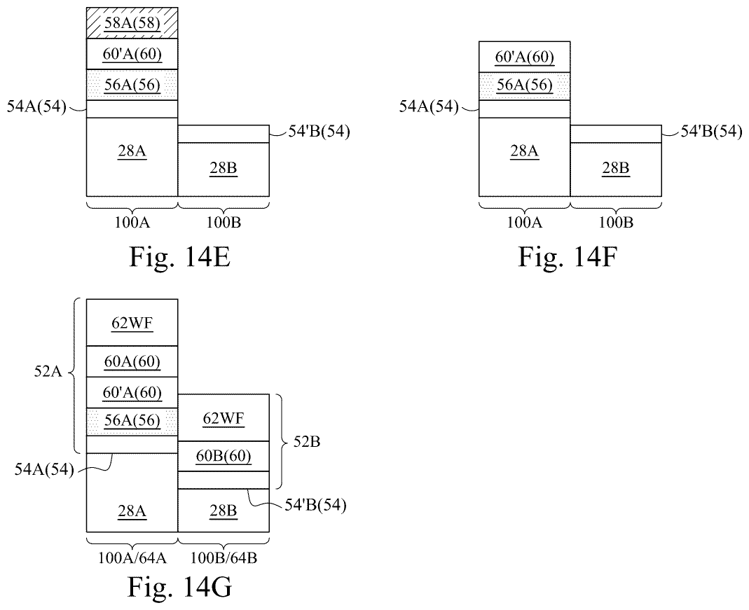

FIGS. 14A through 14G illustrate the formation of gate stacks in accordance with alternative embodiments. These embodiments are similar to the combination of the embodiments as shown in FIGS. 12A through 12D and the embodiments as shown in FIGS. 13A through 13E. Accordingly, the formation process includes both of the re-formation of an interfacial layer and the formation of an additional high-k dielectric layer.

The initial processes as shown in FIGS. 14A through 14C are the same as shown in FIGS. 13A-13C, in which high-k dielectric layer 60′ is formed in device region 100A. The details of the processes are not repeated. Next, IL 54B, which has thickness T2 (FIG. 14C) greater than thickness T1, is removed, and the resulting structure is shown in FIG. 14D. Referring to FIG. 14E, IL 54′B is re-formed in device region 100B, and may have a thickness smaller than the removed IL 54B. The hard mask 58 is then removed, and the resulting structure is shown in FIG. 14F. FIG. 14G illustrates the formation of high-k dielectric layer 60 and the work-function layer 62WF.

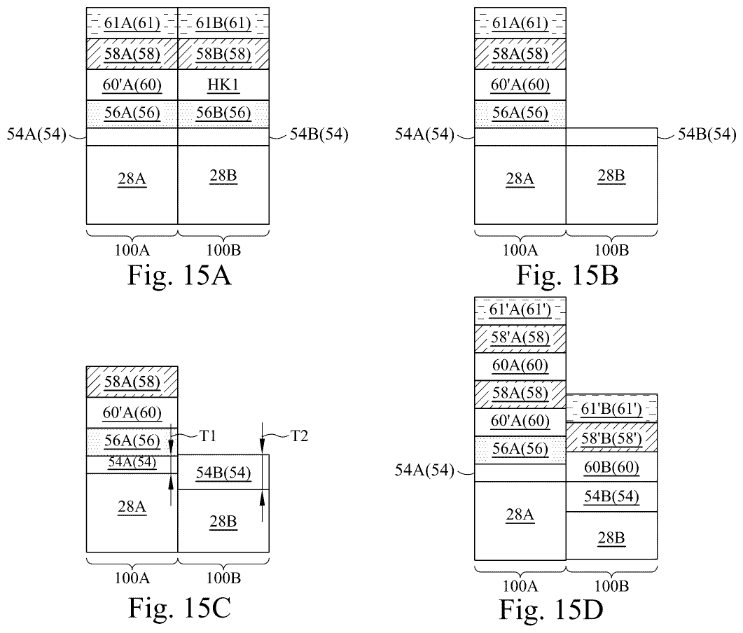

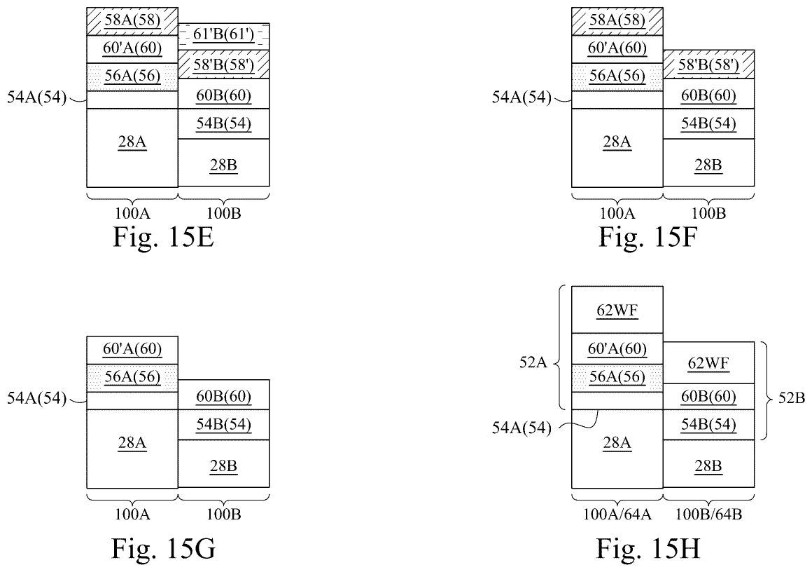

FIGS. 15A through 15H illustrate the formation of gate stacks in accordance with alternative embodiments. These embodiments are similar to the embodiments as shown in FIGS. 13A through 13E, except that instead of stacking the second high-k dielectric layer 60 on top of the first high-k dielectric layer 60′ in device region 100A, the second high-k dielectric layer 60 is also removed from the device region 100A through a patterning process. Also, there is no re-formation of ILs.

The initial processes as shown in FIGS. 15A through 15C are the same as shown in FIGS. 14A-14C (and FIGS. 13A-13C), and the details are not repeated herein. Next, Referring to FIG. 15D, high-k dielectric layer 60 and hard mask 58′ are deposited. The material of high-k dielectric layer 60 may be the same as or different from the material of high-k dielectric layer 60′, and may be selected from the same group of candidate materials of high-k dielectric layer 60′. The material of hard mask 58′ may be the same as or different from the material of hard mask 58, and may be selected from the same group of candidate materials of hard mask 58. Hard mask 58′ includes portion 58′A in device region 100A and portion 58′B in device region 100B. Etching mask 61′A is then formed. Etching mask 61′A also includes portion 61′A in device region 100A and portion 61′B in device region 100B.

FIG. 15E illustrates the patterning processes for removing portion 61′A of etching mask 61′ and portion 58′A of hard mask 58′ from device region 100A. Next, etching mask 61′B is removed, and the resulting structure is shown in FIG. 15F. FIG. 15G illustrates the removal of both of hard mask 58′ and hard mask 58. FIG. 15H illustrates the formation of work function layer 62WF. In the resulting structure, high-k dielectric layers 60′A and 60B may be formed of the same or different high-k dielectric material, and/or may have the same or different thicknesses. FIG. 15H illustrates the formation of work-function layer 62WF.

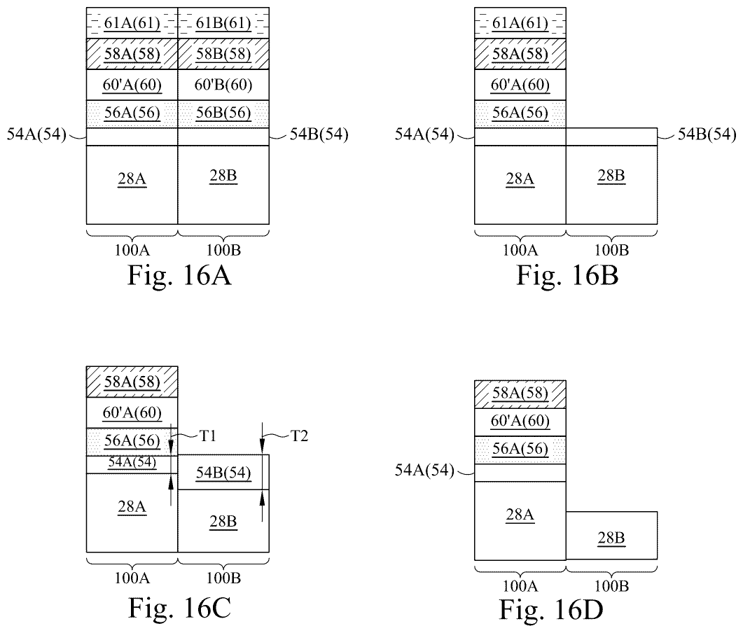

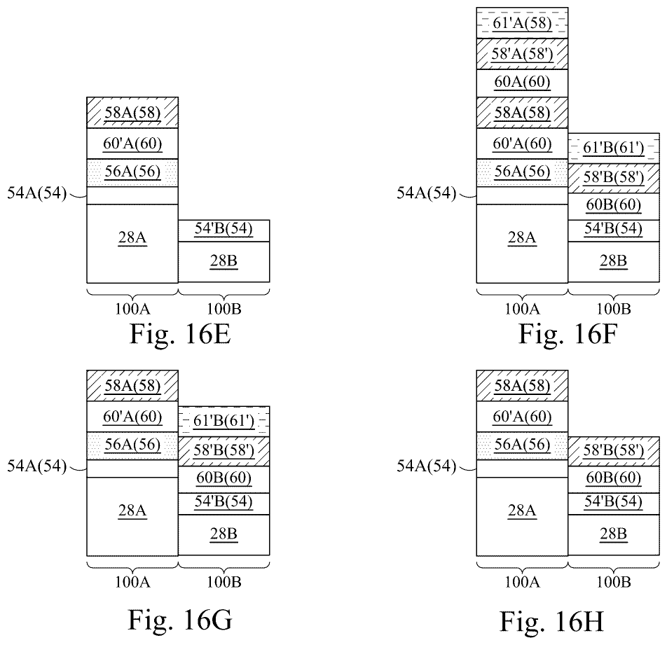

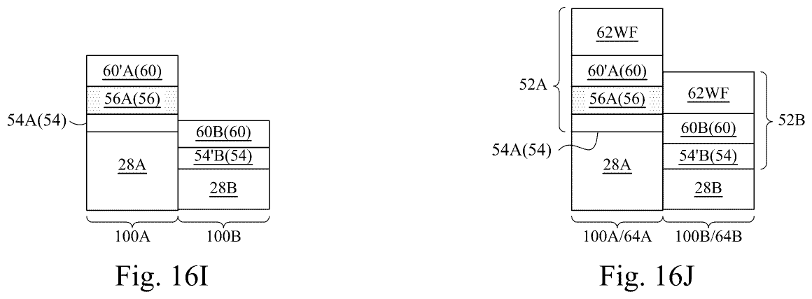

FIGS. 16A through 16H illustrate the formation of gate stacks in accordance with alternative embodiments. These embodiments are similar to the embodiments as shown in FIGS. 15A through 15H, except that an additional IL re-formation process is performed.

The initial processes as shown in FIGS. 16A through 16C are the same as shown in FIGS. 15A-15C, and the details are not repeated herein. Next, the IL 54B is removed, as shown in FIG. 16D, followed by the re-formation of IL 54′B as shown in FIG. 16E. FIGS. 16F, 16G, 16H, 16I, and 16J are essentially the same as shown FIGS. 15D, 15E, 15F, 15G, and 15H, respectively, and are not repeated herein.

The formation of the gate dielectrics incorporating a dipole film may also be used in the formation of the other types of transistors other than FinFETs. For example, FIG. 17 illustrates an intermediate stage in the formation of gate dielectric 57 for a GAA transistor. Gate dielectrics 57 are formed to wrap around nanostructures 122B, which may be silicon nanosheets. Gate dielectrics 57 may have any of the structures shown in previous embodiments, and may include a dipole film between the IL and the corresponding high-k dielectric layer. Also, in the same device die, the inner sidewalls of inner spacers 124 may have the dipole dopant incorporated therein due to the formation of the dipole film.

FIG. 18 illustrates the distribution of the dipole dopant in gate stack 52A (FIG. 9) in accordance with some embodiments. In accordance with some embodiments, since the dipole film 56A is very thin, it may be, or may not be identifiable as a separate layer, and hence dipole film 56A is shown as being comprises as parts of the IL 54A and high-k dielectric layer 60A. Since dipole film 56A is formed between IL 54A and the overlying high-k dielectric layer 60A, the peak dipole dopant concentration and the peak dipole dopant atomic percentage of the dipole film may be in middle between IL 54A and high-k dielectric layer 60A when dipole film 56A is noticeable as a separate film. Also, when the dipole dopant in dipole film 56A is diffused into IL 54A and high-k dielectric layer 60A and is no longer noticeable as a separate film, the peak dipole dopant concentration may be at the interface of IL 54A and high-k dielectric layer 60A.

The embodiments of the present disclosure have some advantageous features. By forming a thin dipole film between an interfacial layer and a high-k dielectric layer, the dipole dopant is readily incorporated into the gate dielectric of the corresponding transistor, and may tune the work function of the resulting transistor. The dipole film thus may be formed very thin without scarifying its effectiveness in tuning effective work function and threshold voltage. The dipole film, due to its small thickness, may remain in the gate stack without noticeably occupying the volume of the gate stack. Accordingly, complementary transistors may adopt the dipole film when the sizes of the transistors are very small, and a common gate electrode may be used to form a pair of complementary transistors.

In accordance with some embodiments, a method comprises forming a first source/drain region based on a first portion of a first semiconductor region; forming a first interfacial layer base on a second portion of the first semiconductor region; forming a first dipole film on the first interfacial layer; depositing a first high-k dielectric layer on the first dipole film; and depositing a first work-function layer on the first high-k dielectric layer. In an embodiment, at a time when the first work-function layer is deposited, the first dipole film remains between the first interfacial layer and the first high-k dielectric layer. In an embodiment, the first source/drain region is of n-type, the first work-function layer is a p-type work-function layer, and the first dipole film comprises an n-type dipole dopant. In an embodiment, the first source/drain region is of p-type, the first work-function layer is an n-type work-function layer, and the first dipole film comprises a p-type dipole dopant.

In an embodiment, the method further comprises forming a second source/drain region based on a first portion of a second semiconductor region; forming a second interfacial layer base on a second portion of the second semiconductor region; forming a second dipole film on the second interfacial layer, wherein the first dipole film and the second dipole are formed in a common deposition process; removing the second dipole film, wherein the first dipole film remains; depositing a second high-k dielectric layer on the second interfacial layer; and depositing a second work-function layer on the second high-k dielectric layer.

In an embodiment, the method further comprises, after the second dipole film is removed, removing the first interfacial layer; and before the depositing the second high-k dielectric layer, forming a replacement interfacial layer. In an embodiment, the method further comprises, before the removing the second dipole film, depositing a third high-k dielectric layer on the first dipole film, wherein the first high-k dielectric layer is deposited on the third high-k dielectric layer.

In an embodiment, the first high-k dielectric layer and the third high-k dielectric layer comprise different high-k dielectric materials. In an embodiment, in an entire period of time starting at a first time the first dipole film is deposited and ending at a second time the first work-function layer starts to be deposited, no drive-in process is performed to drive dipole dopants in the first dipole film into the first interfacial layer. In an embodiment, a peak dipole dopant of the first dipole film is in middle between the first interfacial layer and the first high-k dielectric layer. In an embodiment, the first dipole film has a thickness smaller than about 1 Å.

In accordance with some embodiments, a method comprises forming a first semiconductor region and a second semiconductor region; forming an interfacial layer comprising a first portion on the first semiconductor region; and a second portion on the first semiconductor region; depositing a dipole film comprising a first portion on the first portion of the interfacial layer; and a second portion on the second portion of the interfacial layer; removing the second portion of the dipole film to reveal the second portion of the interfacial layer; depositing a high-k dielectric layer comprising a first portion on the first portion of the dipole film; and a second portion on the second portion of the interfacial layer; and depositing a work-function layer on the high-k dielectric layer.

In an embodiment, the method further comprises forming an n-type source/drain region on a side of the first semiconductor region, wherein the dipole film comprises an n-type dipole dopant. In an embodiment, the method further comprises forming a p-type source/drain region on a side of the first semiconductor region, wherein the dipole film comprises a p-type dipole dopant.

In accordance with some embodiments, a device comprises a first semiconductor region; a second semiconductor region adjacent to the first semiconductor region; a first gate stack comprising a first interfacial layer on the first semiconductor region; a dipole film on the first interfacial layer; a first high-k dielectric layer on the dipole film; a first work-function layer on the first high-k dielectric layer; and a first filling metal region over the first work-function layer; and a second gate stack comprising a second interfacial layer on the second semiconductor region; a second high-k dielectric layer over and in contact with the second interfacial layer; a second work-function layer on the second high-k dielectric layer; and a second filling metal region over the second work-function layer, wherein the first filling metal region and the second filling metal region are joined with each other and are formed of a same metallic material. In an embodiment, the first filling metal region and the second filling metal region are portions of a continuous and homogeneous metal region.

In an embodiment, a peak concentration of a dipole dopant in the dipole film is at middle of the dipole film. In an embodiment, the first work-function layer is a p-type work-function layer, and the dipole film comprises an n-type dipole dopant. In an embodiment, the first work-function layer is an n-type work-function layer, and the dipole film comprises a p-type dipole dopant. In an embodiment, the device further comprises a third high-k dielectric layer between the first work-function layer and the first high-k dielectric layer, wherein the first high-k dielectric layer is formed of a same material as the third high-k dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain region in a first semiconductor region;
removing a dummy gate stack aside of the first source/drain region to form a recess;
forming a first interfacial layer in the recess and over the first semiconductor region;
depositing a first dipole film on the first interfacial layer, wherein the first dipole film has a first conductivity type;
depositing a first high-k dielectric layer over the first dipole film; and
depositing a first work-function layer over the first high-k dielectric layer, wherein the first work-function layer comprises a material that has a second conductivity type opposite to the first conductivity type, and wherein the first dipole film is configured to tune the first work-function layer to have an effective work function of the first conductivity type.

2. The method of claim 1, wherein at a time when the first work-function layer is deposited, the first dipole film remains between the first interfacial layer and the first high-k dielectric layer.

3. The method of claim 1, wherein the first source/drain region is of n-type, the first work-function layer comprises a p-type work-function material, and wherein the first dipole film results in the first work-function layer to have the effective work function of n-type.

4. The method of claim 1, wherein the first source/drain region is of p-type, the first work-function layer comprises an n-type work-function material, and wherein the first dipole film results in the first work-function layer to have the effective work function of p-type.

5. The method of claim 1 further comprising:
forming a second source/drain region in a second semiconductor region, the second source/drain region being of an opposite conductivity type than the first source/drain region;
forming a second interfacial layer over the second semiconductor region;
depositing a second dipole film over the second interfacial layer, wherein the first dipole film and the second dipole film are deposited in a same deposition process;
removing the second dipole film;
depositing a second high-k dielectric layer over the second interfacial layer; and
depositing a second work-function layer over the second high-k dielectric layer.

6. The method of claim 5, wherein the first work-function layer is physically joined to the second work-function layer, and wherein the first work-function layer and the second work-function layer are parts of a same continuous work function layer, and are formed simultaneously.

7. The method of claim 5 further comprising:
after the second dipole film is removed, further removing the second interfacial layer; and
before the depositing the second high-k dielectric layer, forming a replacement interfacial layer.

8. The method of claim 5 further comprising:
before the removing the second dipole film, depositing a third high-k dielectric layer over the first dipole film.

9. The method of claim 8, wherein the first high-k dielectric layer and the third high-k dielectric layer comprise different high-k dielectric materials.

10. The method of claim 1, wherein in an entire period of time starting at a first time the first dipole film is deposited and ending at a second time the first work-function layer starts to be deposited, no drive-in process is performed to drive dipole dopants in the first dipole film into the first interfacial layer.

11. The method of claim 1, wherein a peak dipole dopant of the first dipole film is in middle between the first interfacial layer and the first high-k dielectric layer.

12. The method of claim 1, wherein the first dipole film has a thickness smaller than about 1 Å.

13. A method comprising:
forming a first source/drain region in a first semiconductor region, wherein the first source/drain region is of a first conductivity type;
forming a second source/drain region in a second semiconductor region, wherein the second source/drain region is of a second conductivity type opposite to the first conductivity type;
forming a first gate stack aside of the first source/drain region comprising:
forming a first interfacial layer over the first semiconductor region;
depositing a first dipole film over the first interfacial layer;
depositing a first high-k dielectric layer over the first dipole film; and
forming a first work-function layer over the first high-k dielectric layer; and
forming a second gate stack aside of the second source/drain region comprising:
forming a second interfacial layer over the second semiconductor region;
depositing a second dipole film over the second interfacial layer;
removing the second dipole film;
depositing a second high-k dielectric layer over the second interfacial layer; and
forming a second work-function layer over the second high-k dielectric layer, wherein the first work-function layer and the second work-function layer are of a same conductivity type.

14. The method of claim 13, wherein the first work-function layer is continuously joined to the second work-function layer.

15. The method of claim 13, wherein the first work-function layer and the second work-function layer are deposited in a same deposition process.

16. The method of claim 15, wherein the first work-function layer is in physical contact with the first high-k dielectric layer, and the second work-function layer is in physical contact with the second high-k dielectric layer.

17. The method of claim 16, wherein the first work-function layer and the second work-function layer are of the second conductivity type, and wherein the first dipole film is configured to tune the first work-function layer to have an effective work function of the first conductivity type.

18. A method comprising:
forming a gate stack comprising:
forming an interfacial layer over a semiconductor region;
depositing a dipole film over the interfacial layer, wherein the dipole film has a first conductivity type;
depositing a high-k dielectric layer on the dipole film;
depositing a conductive material over the high-k dielectric layer, wherein the conductive material has a work function that has a second conductivity type opposite to the first conductivity type, and wherein the conductive material acts as a work-function layer that has an effective work function of the first conductivity type; and
a filling metal region over the work-function layer.

19. The method of claim 18, wherein the conductive material physically contacts the high-k dielectric layer.

20. The method of claim 18 further comprising forming a source/drain region, wherein the source/drain region and the gate stack collectively form parts of a transistor, and wherein the source/drain region is of the first conductivity type.
